(19) United States
(12) Patent Application Publication
(10) Pub. No.: US 2006/0006401 A1
(43) Pub. Date: Jan. 12, 2006

(54) Flip chip light emitting diode

(76) Inventor: Hsing Chen, HsinChu (TW)

Correspondence Address: PRO-TECHTOR INTERNATIONAL, 20775 Norada Court, Saratoga, CA, 95070-3018, US

(21) Appl. No.: 10/887,668

(22) Filed: Jul. 8, 2004

(51) Int. Cl. H01L 29/22

(52) U.S. Cl. 257/98; 257/79; 257/432

(57) ABSTRACT

A flip chip light emitting diode structure includes a substrate, a LED chip, and a low refractive index layer. The substrate is formed of a substantially transparent material, which includes a top surface and a lower surface. The LED chip has a first surface and a second surface. The first surface is mounted on the lower surface of the substrate. The second surface is formed with a N-electrode and a P-electrode. The low refractive index layer is mounted on the top surface of the substrate. The refractive index of the low refractive index layer is lower than that of the substrate, and higher than that of the atmosphere.

### BACKGROUND OF THE INVENTION

1. Field of the invention

The invention pertains to a flip chip light emitting diode structure. More particularly, the invention relates to a flip chip light emitting diode that is easy to be fabricated and capable of increasing the lifetime of the product.

2. Description of the Related Art

Referring to FIG. 1, a conventional light emitting diode structure includes a substrate 3, an LED chip 1, and an epoxy-compound resin 2. The LED chip 1 is mounted on the substrate 3 and is electrically connected the substrate 3 by wires.

According to the above-mentioned structure, the overall volume of the conventional light emitting diode is too large. The size of the conventional LED is limited by its structure, therefore, it is very different to reduce the dimension of the LED to be thinner, smaller and lighter.

It is very also important how to obtain high heat dissipation LED. In particular, a white light emitting diode may be produced to generate high heat energy, therefore, the heat dissipation effect is very important. But, because epoxy-compound resin is a transparent paste, which has a poor thermal conductivity, the heat energy generated by LED chip when applied a higher current may not be dissipated. A conventional light emitting diode may not be manufactured to apply high current, such as lighting, back-lighting applications. Therefore, how to omit the epoxy-compound resin is very important in LED package technology.

However, when omit the epoxy-compound resin, the light generated by light emitting diode cannot be refracted, and the brightness of the light emitting diode is reduced drastically.

### SUMMARY OF THE INVENTION

An objective of the invention is to provide a flip chip light emitting diode structure that the lifetime of the product can be prolonged effectively.

Another objective of the invention is to provide a light emitting diode structure that the brightness of the product can be increased.

Another objective of the invention is to provide a light emitting diode structure that the size of the LED can be produced to be lighter, thinner, and smaller than that of the conventional LED.

To achieve the above-mentioned objective, the invention includes a substrate, a LED chip, and a low refractive index layer. The substrate is formed of a substantially transparent material, which includes a top surface and a lower surface. The LED chip has a first surface and a second surface, the first surface of the LED is mounted on the lower surface of the substrate, the second surface is formed with a N-electrode and a P-electrode. The low refractive index layer is mounted on the top surface of the substrate, the refractive index of the low refractive index layer is lower than that of the substrate, and higher than that of the atmosphere.

Therefore, the light generated by LED chip 4 can be refracted, so that the brightness of the light emitting diode may be promoted, and can be produced to be lighter, thinner, and smaller.

### BRIEF DESCRIPTION OF THE DRAWINGS

FIG. 1 is a cross-sectional view showing a conventional light emitting diode structure.

FIG. 2 is the first schematic illustration showing a flip chip light emitting diode structure of the present invention.

FIG. 3 is the second schematic illustration showing a flip chip light emitting diode structure of the present invention.

FIG. 4 is the third schematic illustration showing a flip chip light emitting diode structure of the present invention.

FIG. 5 is the fourth schematic illustration showing a flip chip light emitting diode structure of the present invention.

FIG. 6 is a cross-sectional schematic illustration showing a flip chip light emitting diode structure connected to a printed circuit board.

FIG. 7 is a cross-sectional schematic illustration showing a flip chip light emitting diode structure coated with a fluorescent paste.

FIG. 8 is a cross-sectional schematic illustration showing a flip chip light emitting diode structure with a transparent lid.

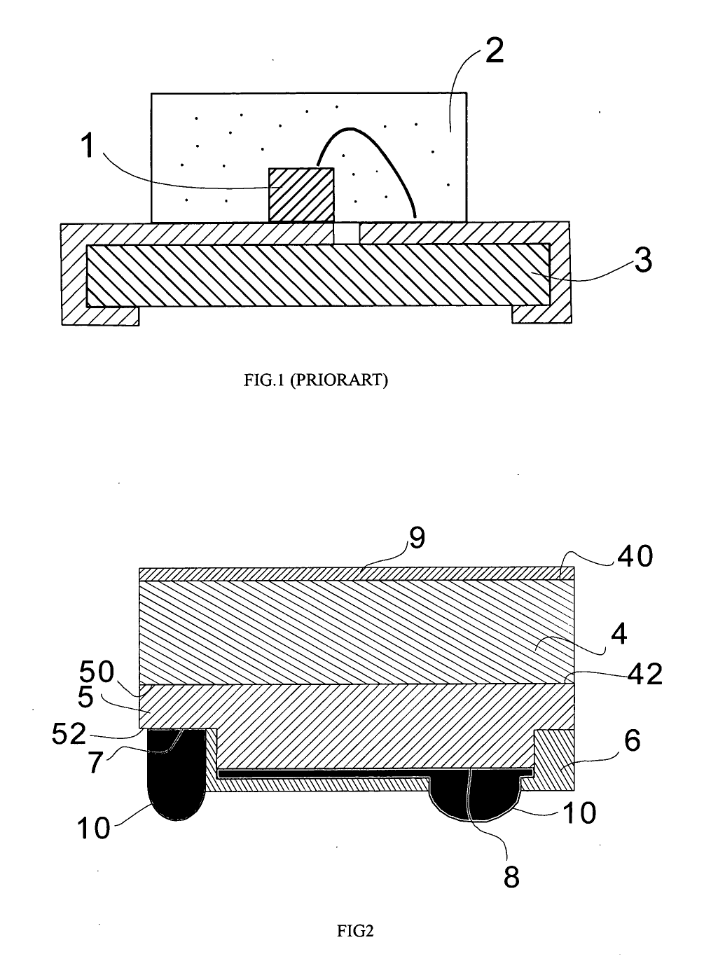

### DETAILED DESCRIPTION OF THE INVENTION

Please refer to FIG. 2, a flip chip light emitting diode structure of the present invention includes a substrate 4, a LED chip 5, and a low refractive index layer 9.

The substrate 4 is formed of a substantially transparent material, which includes a top surface 40 and a lower surface 42.

The LED chip 5 has a first surface 50 and a second surface 52, which is formed with an N-electrode 7 and a P-electrode 8. The first surface 50 of the LED chip 5 is mounted on the lower surface 42 of the substrate 4. Wherein the P-electrode 8 of the LED chip is coated with an insulation layer 6, which is formed of Si O₂ film or Si₃ N₄ film. The N-electrode 7 and P-electrode 8 of the LED chip are formed with bonding pads, each bonding pads include a flip chip solder bump 10.

The low refractive index layer 9 is mounted on the top surface 40 of the substrate 4, the refractive index of the low refractive index layer 4 is lower than that of the substrate 4, and higher than that of the atmosphere.

In the embodiment, the low refractive index layer is formed of Si O₂ film or Si₃ N₄ film. Therefore, the light generated by light emitting diode can be refracted via the low refractive index layer to increase the brightness of the light emitting diode.

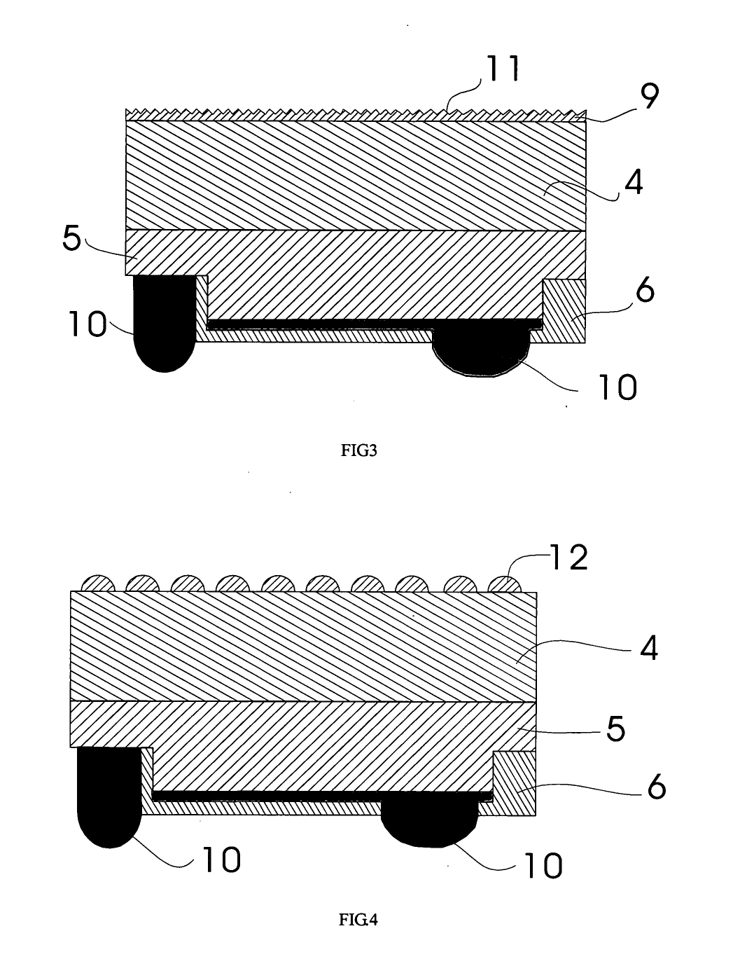

Please refer to FIG. 3, it is the second schematic illustration showing a flip chip light emitting diode structure of the present invention. Wherein the low refractive index layer 9 is formed with a rough surface 11 by etching. Thus, the light generated by light emitting diode can obtain a better refractive through the rough surface of the low refractive index layer to increase the brightness of the light emitting diode.

Please refer to FIG. 4, it is the third schematic illustration showing a flip chip light emitting diode structure of the present invention. The light emitting diode comprises a substrate 4 and an LED chip 5. The top surface 40 of the substrate 4 is formed with a plurality of lens 12 by etching. The lens 12 are formed of Zn O, Si O₂, Si₃N₄, Zn Se, GaN or ITO etc.

Thus, the light generated by light emitting diode can obtain a better refractive through lens 12 to increase the brightness of the light emitting diode.

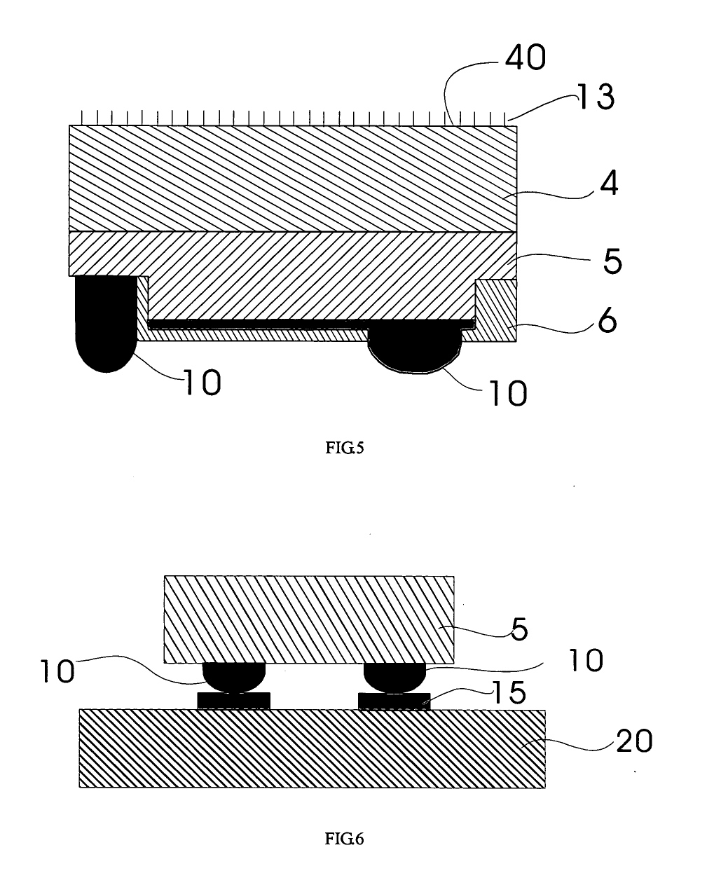

Please refer to FIG. 5, it is the third schematic illustration showing a flip chip light emitting diode structure of the present invention. The light emitting diode comprises a substrate 4 and an LED chip 5. The top surface 40 of the substrate 4 is formed with a plurality of tiny posts 13 by etching. The tiny posts 13 are formed of Zn O, Si O₂, Si₃ N₄, Zn Se, GaN or ITO etc.

Thus, the light generated by light emitting diode can obtain a better refractive index through tiny posts 13 to increase the brightness of the light emitting diode.

Please refer to FIG. 6, it is a cross-sectional schematic illustration showing a flip chip light emitting diode structure connected to a printed circuit board. The flip chip solder bump 10 of the LED chip 5 is electrically connected to the electrode 15 of the printed circuit board 20 by SMT.

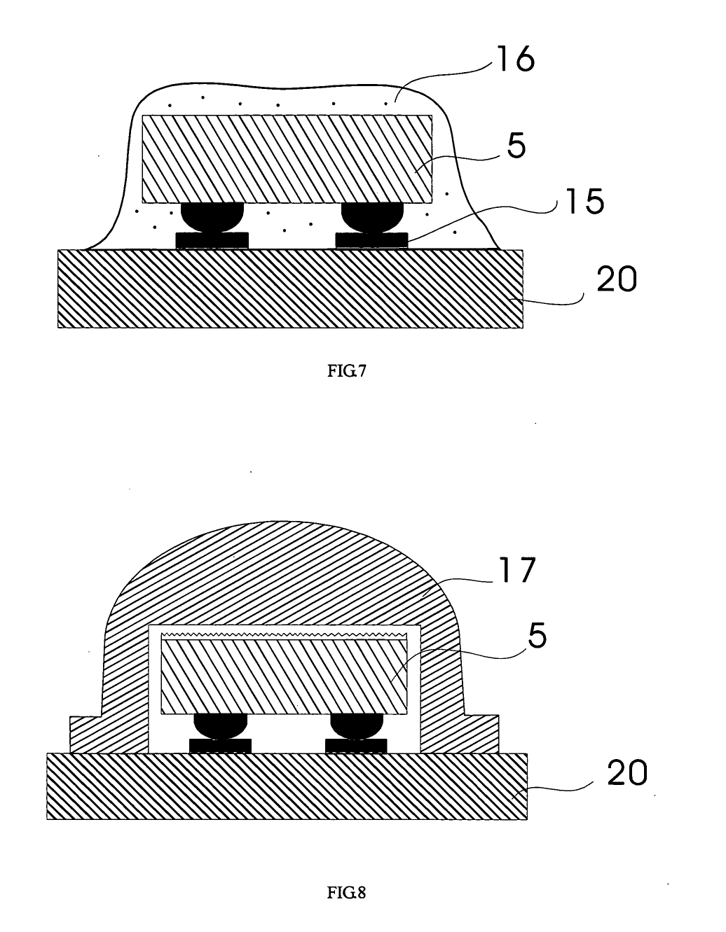

Please refer to FIG. 7, it is a cross-sectional schematic illustration showing a flip chip light emitting diode structure coated with a fluorescent paste. After the LED chip 5 is electrically connected to the printed circuit board 20, a fluorescent paste 16 is coated over the LED chip 5 by printing to form white light emitting diode or mixture light.

Please refer to FIG. 8, it is a cross-sectional schematic illustration showing a flip chip light emitting diode structure with a transparent lid. After the LED chip 5 is electrically connected to the printed circuit board 20, a transparent lid 17 is covered onto the LED chip to enable the light generated by LED chip with focusing purpose.

While the invention has been described by the way of an example and in terms of a preferred embodiment, it is to be understood that the invention is not limited to the disclosed embodiment. On the contrary, it is intended to cover various modifications. Therefore, the scope of the appended claims should be accorded to the broadest interpretation so as to encompass all such modifications.

What is claimed is:

1. A flip chip light emitting diode structure comprising:
a substrate formed of a substantially transparent material, which includes a top surface and a lower surface;
an LED chip having a first surface and a second surface, the first surface mounted on the lower surface of the substrate, the second surface formed with a N-electrode and a P-electrode;
a low refractive index layer mounted on the top surface of the substrate, the refractive index of the low refractive index layer is lower than that of the substrate, and higher than that of the atmosphere.

2. The flip chip light emitting diode structure according to claim 1, wherein the P-electrode of the LED chip is coated with an insulation layer.

3. The flip chip light emitting diode structure according to claim 1, wherein the low refractive index layer is a Si O₂ or Si ₃N₄.

4. The flip chip light emitting diode structure according to claim 1, wherein the low refractive index layer is formed with a rough surface by etching.

5. The flip chip light emitting diode structure according to claim 1, wherein the N-electrode and P-electrode of the LED chip are formed with bonding pads, each bonding pads include a flip chip solder bump.

6. A flip chip light emitting diode structure comprising:
a substrate formed of a substantially transparent material, which includes a top surface and a lower surface, the top surface is formed with rough surface;
a LED chip having a first surface and a second surface, the first surface mounted on the lower surface of the substrate, the second surface formed with a N-electrode and a P-electrode.

7. The flip chip light emitting diode structure according to claim 1, wherein the P-electrode of the LED chip is coated with an insulation layer.

8. The flip chip light emitting diode structure according to claim 1, wherein the rough of the top surface of the substrate is formed of a plurality of substantially transparent tiny posts.

9. The flip chip light emitting diode structure according to claim 1, wherein the rough of the top surface of the substrate is formed of a plurality of substantially transparent lens.

10. The flip chip light emitting diode structure according to claim 1, wherein the substantially transparent tiny posts or lens is formed of ZnO, Si O₂, Si₃N₄, Zn Se, GaN or ITO etc.
